(19) United States
(12) Patent Application Publication
(10) Pub. No.: US 2026/0177883 A1
(43) Pub. Date: Jun. 25, 2026

(54) Photonic Static Random Access Memory

(71) Applicant: Wisconsin Alumni Research Foundation, Madison, WI (US)

(72) Inventors: Akhilesh Jaiswal, Madison, WI (US); Md Abdullah-AI Kaiser, Irvine, CA (US); Sugeet Sunder, Waltham, MA (US); Ajey Jacob, Watervliet, NY (US)

(21) Appl. No.: 18/989,456

(22) Filed: Dec. 20, 2024

(51) Int. Cl. G02F 3/02; G11C 13/04

(52) U.S. Cl. CPC G02F 3/02; G11C 13/047

(57) ABSTRACT

A photonic random access memory employs series connected photosensors to define switching nodes driving optical modulators, the series connection operating to reduce the effect of photosensor dark current.

### STATEMENT REGARDING FEDERALLY SPONSORED RESEARCH OR DEVELOPMENT

### CROSS REFERENCE TO RELATED APPLICATION

### BACKGROUND OF THE INVENTION

The present invention relates to static random-access memories (SRAM) and, in particular, to a photonic SRAM employing a differential or balanced photodiode structure.

High-speed random-access memory is a fundamental component of modern computer systems and may operate by storing binary data as electrical charge, for example, in a capacitor element. Such electrical memory systems are limited by slow and energy expensive data access and the limiting speeds of electrical interconnection buses.

For this reason there is considerable interest in photonic or optical random-access memory. These memories can provide instantaneous, low-energy data access and extremely high interconnection bandwidth comparable with light communication.

US patent application 2024/0170055, assigned to the University of Southern California and hereby incorporated by reference, describes a high-speed optical random-access memory employing a combination of optical modulators (micro resonant rings) and photosensors operating to provide bistable elements that can store data. The photosensors, which may be photodiodes or photo transistors, must be specially selected to have low leakage or dark currents in order to ensure that they quickly and consistently optical modulators to turn off the optical modulators as needed. Such devices can be expensive and/or difficult to fabricate using preferred integrated circuit processes such as those used for complementary metal-on-oxide (CMOS) fabrication.

### SUMMARY OF THE INVENTION

The present invention provides an optical memory architecture using series-connected photosensors, such as photodiodes, to reduce the effect of dark or leakage current allowing improved manufacturability of a high-speed photonic memory while allowing better cross-coupling between optical modulators.

In one embodiment, the invention provides a memory cell having a first and second optical modulator. Each optical modulator has a light input and at least one light output and receives an electrical input determining a switching state of the optical modulator defining a switching of light between the light input and light output. A first photodiode is connected to conduct current to a first node when illuminated, and a second photosensor is connected to conduct current away from the first node when illuminated. Similarly, a third photosensor is connected to conduct current to a second node when illuminated, and a fourth photosensor is connected to conduct current away from the second node when illuminated. The first and second optical modulators control light directed to at least one of a respective photosensor and have their electrical inputs connected to one of the first and second nodes to provide bistable switching states.

It is thus a feature of at least one embodiment of the invention to use balanced pairs of photosensors to reduce the effect of photosensor current leakage.

In one embodiment, the memory cell may further include a first electrical switch operating to block current flow through the first photosensor when the first node is below a threshold voltage and a second electrical switch operating to block current flow through the second photosensor when the first node is above the threshold voltage. Similarly, a third switch may operate to block current flow through the third photosensor when the second node is below the threshold voltage, and a fourth electrical switch may operate to block current flow through the fourth photosensor when the second node is above the threshold voltage.

It is thus a feature of at least one embodiment of the invention to further reduce dark current leakage through auxiliary blocking transistors causing status power dissipation.

Optionally, the first and second electrical switches may communicate with a first electrical buffer amplifier having an input attached to the first node, and the third and fourth electrical switches may communicate with a second electrical buffer amplifier having an input attached to the second node.

It is thus a feature of at least one embodiment of the invention to provide a low impedance driver for the electrical switches improving switching speed and to provide a high gain switching against a threshold for rapid switching transition.

In this embodiment, the memory cell may further include a fifth electrical switch operating to shunt the first electrical switch and a sixth electrical switch operating to shunt the second electrical switch and a seventh electrical switch operating to shunt the third electrical switch and an eighth electrical switch operating to shunt the fourth electrical switch. The fifth, sixth, seventh, and eighth electrical switches are adapted to receive a write signal to move them to a shunting state during a writing of data to the memory cell, such writing as operates to change the bistable switching state.

It is thus a feature of at least one embodiment of the invention to allow a bypassing of the leakage current blocking transistors when fast writes to memory are required.

In one embodiment, the first and second optical modulators each have a light input receiving light that can be switchably directed to either of a THROUGH output or a DROP output and wherein the first and second optical modulator control illumination of the first, second, third, and fourth photosensors by conducting light to the respective photosensors from the DROP light output.

It is thus a feature of at least one embodiment of the invention to use the DROP output of the optical modulator to provide a wider passband for multifrequency operation.

In one embodiment, the first optical modulator controls light to the first and second photosensors and the second optical modulator controls light to the third and fourth photosensor and wherein the second optical modulator is connected to the first node and the first optical modulator is connected to the second node.

It is thus a feature of at least one embodiment of the invention to provide a design that minimizes crossing optical conduits for improved fabrication efficiency.

Alternatively, the first optical modulator may control light to the third and fourth photosensors and the second optical modulator controls light to the first and second photosensor when the second optical modulator is connected to the second node and the first optical modulator is connected to the first node.

It is thus a feature of at least one embodiment of the invention to provide an alternative cross coupling that eliminates the need for additional splitters.

The memory cell may further include two optical conduits receiving a SET signal or RESET signal, respectively, to change the bistable switching state and operating to conduct light each to a photosensor associated with a different node.

It is thus a feature of at least one embodiment of the invention to provide for a simple optical writing of the memory cell.

Similarly, the memory cell may include two optical conduits each connected to communicate with a different one of the optical modulators to provide a light output indicating the bistable switching state. In one case the optical conduits may communicate with respective optical modulators using a splitter transmitting less part of the light from the optical modulator to the optical conduit.

It is thus a feature of at least one embodiment of the invention to provide an optical output without affecting the stability of the memory cells during reading.

Alternatively, the read optical conduits may be connected directly to an output of an optical modulator not providing light to a photosensor.

It is thus a feature of at least one embodiment of the invention to adopt a memory cell configuration that eliminates the need for a splitter to extract read light.

The memory cell may include an optical conduit for receiving an operand signal and further including at least one third optical switch communicating with at least one of the nodes to switch light to a second product output optical conduit depending on the state of the bistable element.

It is thus a feature of at least one embodiment of the invention to provide for in-memory computation at extremely high speeds using optical signals.

This embodiment may further include multiple third optical modulators, each communicating with one of the nodes to switch light to a second product output optical conduit depending on the state of the bistable element. The multiple third optical modulators may each provide a different on-state frequency offset of a passband or rejection band.

It is thus a feature of at least one embodiment of the invention to provide simultaneous computations of parallel optical signals at different center frequencies.

These particular objects and advantages may apply to only some embodiments falling within the claims and thus do not define the scope of the invention.

### BRIEF DESCRIPTION OF THE DRAWINGS

FIG. 1 is a block diagram of an optical memory array of multiple memory cells such as may implement the present invention, showing generally its interface to conventional electronic signal pathways;

FIG. 2 is a first embodiment of the memory cell of FIG. 1 providing photosensors and optical modulators in which symbols are explained within key captions contained in dotted lines;

FIG. 3 is a schematic representation of one embodiment of an optical modulator showing a light path and a frequency response of the optical modulator in an off state;

FIG. 4 is a figure similar to FIG. 3 showing a light path and a frequency response of the optical modulator and an on state;

FIG. 5 is a figure similar to FIG. 4 showing an alternative embodiment employing a different cross connection between optical modulators and a photosensor;

FIG. 6 is a figure similar to that of FIG. 4 showing an embodiment in which two pole optical modulators may be used;

FIG. 7 is a figure similar to FIG. 6 using a two-pole optical modulator but employing the DROP rather than the THROUGH output;

FIG. 8 is a figure similar to FIG. 4 showing leakage reducing transistors with an optional buffer amplifier;

FIG. 9 is a figure similar to FIG. 8 showing shunting transistors that can shunt the leakage reducing transistors during write operations;

FIG. 10 is a figure similar to FIG. 1 showing the use of a buffer amplifier between nodes and the optical modulators;

FIG. 11 is a depiction of the memory cell as may be integrated into an array having write lines and bit lines;

FIG. 12 is a figure similar to FIG. 11 eliminating the need for a splitter for reading;

FIG. 13 is a figure. showing a memory cell incorporated into an in-memory computational system;

FIG. 14 is a figure similar to FIG. 2 showing a reduced part count version of the memory cell;

FIG. 15 is a figure similar to FIG. 2 showing read and write lines that are decoupled; and

FIG. 16 is a figure similar to FIG. 15 showing an alternative embodiment of decoupled read and write lines.

### DETAILED DESCRIPTION OF THE PREFERRED EMBODIMENT

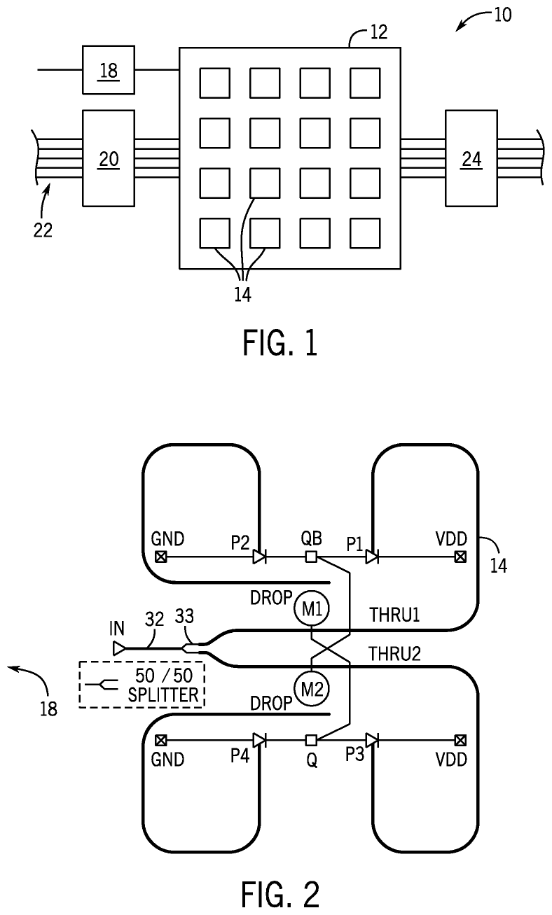

Referring now to FIG. 1, the present invention provides a memory system 10 having an array 12 of memory cells 14, the latter of which each may operate to store a bit of data representing a logical zero or one value. The memory cells 14 are typically arranged in logical rows and columns (often reflecting actual physical arrangement) and may be constructed on a single integrated circuit substrate, for example, compatible with complementary metal-oxide-semiconductor (CMOS) fabrication or may be constructed on different substrates and heterogeneously integrated.

During operation, the memory cells 14 will receive a powering laser light from a laser 18 and will store data according to the path of that light through bistable elements of the memory cells 14 as will be described in more detail below.

Writing data to the memory cells 14 is performed by light signals from a switched laser source 20, the light signals providing independent data for a set of bit lines and column lines used to address individual memory cells 14. Other light signals from the switched laser source 20 can be used to provide operand data when the memory cells 14 are used for in-memory computation. Typically, the laser source 20 may be controlled by conventional electrical signals 22 allowing the memory system 10 to be integrated into a conventional electrical computer or other types of hardware.

Reading data from the memory cells 14 will be performed by a photodetector array 24 which may receive light signals from the memory cells 14 representing stored data or the results of computations when the memory cells 14 are used in-memory computation. The photodetector array 24 may also output electrical signals for the purpose of integrating the memory system 10 with a conventional computer or other hardware.

### Example 1

Referring now to FIG. 2, in a first embodiment the memory cell 14 may provide a first and second optical modulator 30 (designated M1 and M2) which may receive input light power along input line 32 from laser 18.

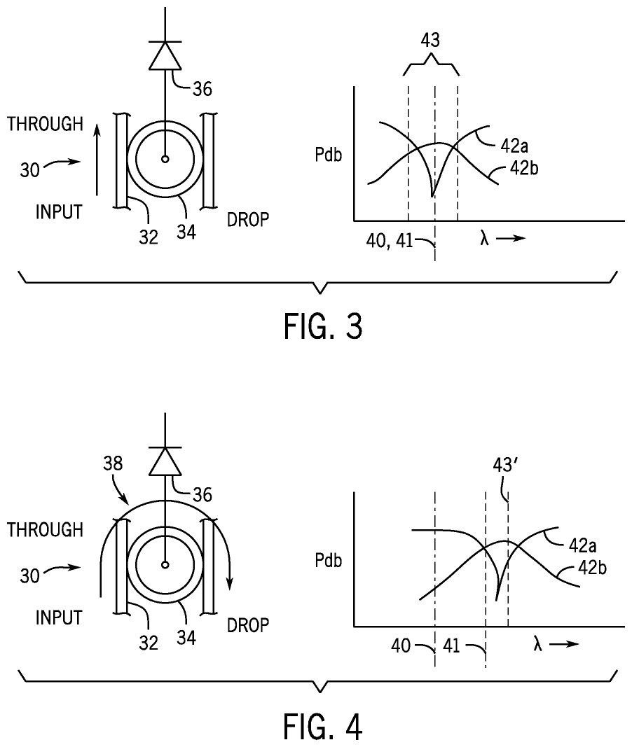

Referring momentarily also to FIGS. 3 and 4, the optical modulators 30 in one embodiment may include a micro ring resonator 34 attached electrically to a photosensor 36 such as a photodiode or phototransistor. The photosensor 36 is biased to provide current to the micro ring resonator 34 during illumination 38 of the photodiode (shown in FIG. 4). More generally, the optical modulators 30 may be selected from a variety of different devices including Mach Zehnder interferometers (MZIs) and electro-absorption based modulators to operate as optical switches as will be discussed below.

When no light is received by the photosensor 36, as shown in FIG. 3, light entering an input waveguide adjacent to the micro ring resonator 34 will pass to a THROUGH output being a continuation of that input waveguide. Conversely when light is received by the photosensor 36, as shown in FIG. 4, the light will be conducted around the micro ring resonator 34 to a DROP output.

The switching operation provided by the micro ring resonator 35 between the THROUGH and the DROP output is caused by a changing in the tuning of the micro ring resonator 34 in turn caused by a changing depletion region of the semiconductor material making up the micro ring resonator 34. This changing depletion region changes an index of refraction of the structure of the micro ring resonator 34 so as to move a resonant frequency 41 from alignment with the center frequency 40 of the laser 18 (when the photosensor 36 is not illuminated) to a position displaced from the center frequency 40 of the laser 18 when the photosensor is illuminated. Generally, a wavelength-dependent transmission 42a at the THROUGH output will show a sharp attenuation region 43 (rejection band) of laser light from the laser 18 when the photosensor 36 is not illuminated (per FIG. 3) and the DROP output will show and a relatively wide passband transmission region 43′ (passband) and a wider bandpass region 43′ (passband) characteristic. When the photosensor 36 is illuminated (per FIG. 4) the THROUGH output will show a relatively high transmission at the frequency 40 of the laser 18 and the DROP output will show a high attenuation of the frequency 40 of the laser 18. The effect is essentially switching light output from the THROUGH output to the DROP output when the photosensor 36 is illuminated.

It will be understood, for example, by review of FIG. 3 that if photosensor 36 without illumination has significant electrical conduction (dark current), the ability to implement this switching will be degraded or lost, with the resonator 34 remaining detuned in both illumination states of the photosensor 36. Further, to the extent that the dark current may be a function of temperature or may vary according to fabrication conditions, the reliability and consistency of the switching may be jeopardized. Specially designed low dark current photosensors 36 may be used but may be prohibitively expensive or incompatible with the desired integrated circuit fabrication techniques and may reduce overall switching speed. The present invention addresses this dark current problem through a design that incorporates series connected photosensors 36 such as photodiodes.

Referring still to FIG. 2, each of the optical modulators M1 and M2 receive, at their inputs, light from laser 18 after passing through a splitter 33. The memory cell 14 further includes four photosensors 36 (designated P1-P4), with photosensors P1 and P2 connected in series between a voltage source (VDD) and ground, with the cathode of P1 connected to the voltage source and the anode of P2 connected to ground so that each photosensor 30 is back biased. The junction between P1 and P2 provides a node QB. Likewise, photosensors P3 and P4 are connected in series between the voltage source (VDD) and ground with the cathode of photosensor P3 connected to the voltage source and the anode of photosensor P4 connected to ground again to be back biased. The junction between P3 and P4 provides a node Q.

In this configuration, optical modulator M1 electrically connects to node Q and optical modulator M2 electrically connects to node QB. The THROUGH output of optical modulator M1 connects to P1 and the DROP output of optical modulator M1 connects to P2. Likewise the THROUGH output of optical modulator M2 connects to P3 and the DROP output of optical modulator M2 connects to P4.

It will be recognized then that this configuration of cross coupling produces a bistable element stably operating in either of two states including a first state where Q is low (low-voltage) and QB is high (high-voltage) and a second state second state where Q is high and QB is low. In the first state, M1 transmits light from its THROUGH output, turning on P1, and does not transmit light through its DROP output, turning off P2, to raise node QB to a high voltage. This high voltage at node QB switches M2 to provide light transmission from its DROP output turning on P4 and to provide no light transmission from its THROUGH output turning off P3 to produce a low value of Q consistent with M1 being in the off state as initially assumed.

In the second state M1 provides light transmission from its DROP output, turning on P2, and no light from its THROUGH output, turning off P1, to lower the voltage of node QB which in turn switches M2 to provide light transmission from its THROUGH output, turning on P3, and no light output from its DROP output, turning off P4, to produce a high-voltage value of Q consistent with M1 being in the on state as assumed.

Dark current passing through the photosensors P1 and P3 is largely offset by the dark current passing through photosensors P2 and P4 by the series connection. In addition, during normal operation, generally when P1 is off (unilluminated) any dark current through P1 will be overwhelmed by the much higher current passing through P2 in the illuminated state, and when P1 is off (unilluminated) any dark current through P2 will be overwhelmed by the much higher current passing through P1 in the illuminated state, because the states of P1 and P2 are consistently in opposition. A similar effect occurs with respect to photosensors P3 and P4.

### Example 2

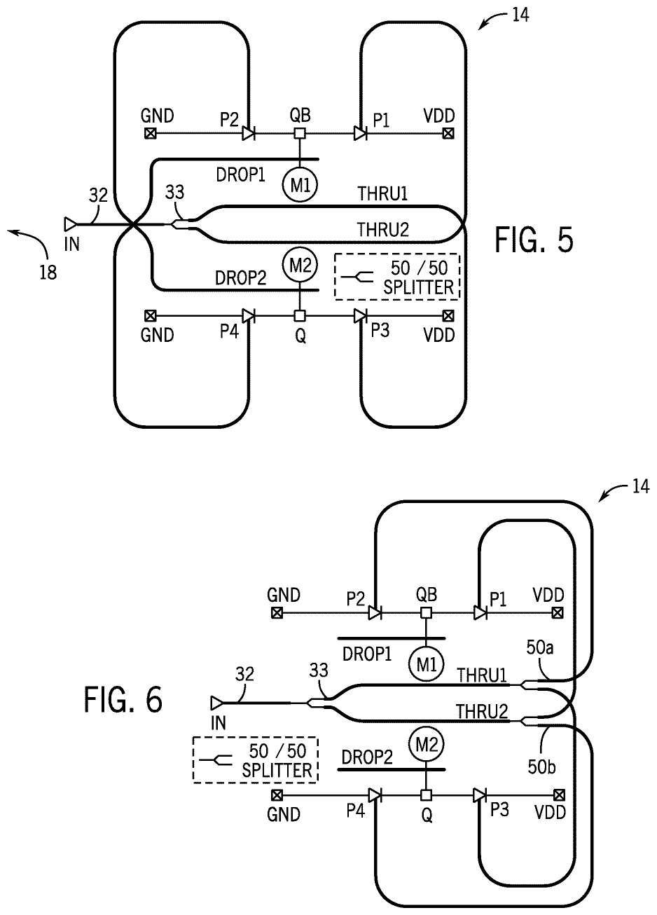

Referring now to FIG. 5, a similar bistability can be obtained by a cross connection that connects optical modulator M1 to node QB and optical modulator M2 to node Q. In this case, the THROUGH output of M1 connects to photosensor P3 and its DROP output connects to photosensor P4. Similarly the THROUGH output of M2 connects to photosensor P1 while the DROP output of M2 connects to photosensor P2.

### Example 3

Referring now to FIG. 6, in an alternative embodiment, only the THROUGH outputs of the optical modulators M1 and M2 are used allowing this circuit to be used with a two-port optical modulator. In this case, as with the embodiment of FIG. 5, again optical modulator M1 is connected to node QB and optical modulator M2 is connected to node Q. The THROUGH output of optical modulator M1 is received by a splitter 50a whose outputs pass to both photosensor P2 and P3. In similar fashion the THROUGH output of optical modulator M2 is received by a splitter 50b communicating with both photosensors P4 and P4. This example of the cross connection also provides for the desired bistability.

### Example 4

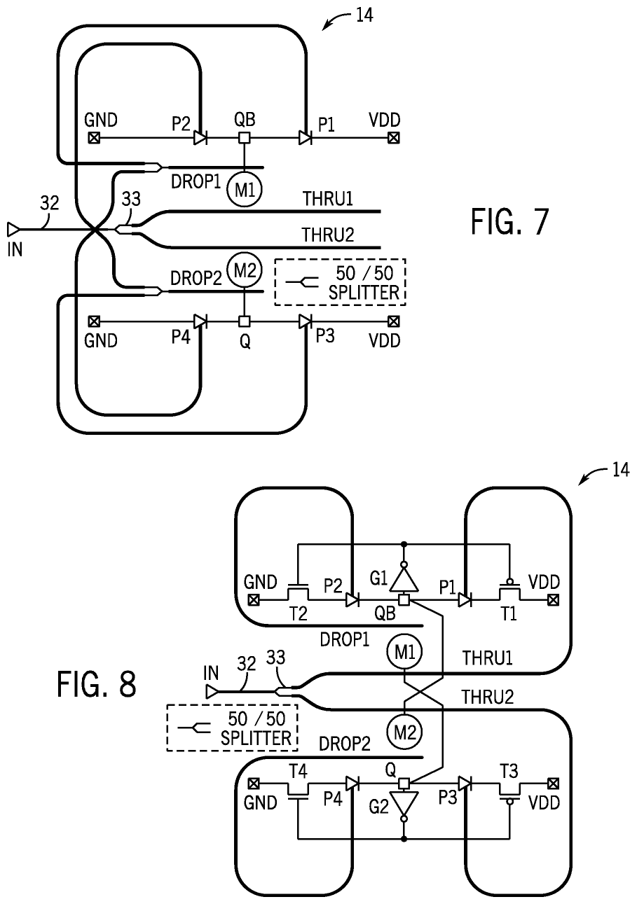

Referring now to FIG. 7, the previous embodiment may be modified so that only the DROP outputs of the optical modulators M1 and M2 are used. Again, this allows a two-port optical modulator to be used but also takes advantage of the broader frequency response of the DROP output shown generally in FIGS. 3 and 4 which may be useful when the optical modulators are used with multiple different frequencies of laser light for parallel operation, for example, in in-memory computation to be described below.

### Example 5

Referring now to FIG. 8, leakage current through the photosensors P1-P4 can be reduced by placing a transistor switch T1 in series with P1 (between P1 and power (VDD)) and transistor T2 in series with P2 (between P2 and ground). These transistors may be controlled by the voltage at the node QB either directly attached to their gates or through a buffer amplifier G1 as shown. The buffer amplifier may, for example, employ the architecture of a CMOS inverter. For proper logic, transistors T1 and T3 may be P-channel MOSFET transistors and transistors T2 and T4 may be N channel MOSFETS.

The amplifier G1 serves to turn on switch T2 and turn off switch T1 when QB is low and to turn off switch T2 and turn on switch T1 when QB is high, thus reducing any dark current flow through the series combination of P1 and P2.

This same structure is duplicated for node Q with a transistor switch T3 in series with P3 between P3 and power (VDD) and transistor T4 in series with P4 between P4 and ground. These transistors may be controlled by the voltage at the node Q either directly or through a buffer amplifier G2 as shown.

Generally these transistors T and optionally amplifiers G can be used in any of the examples provided herein according to this teaching.

### Example 6

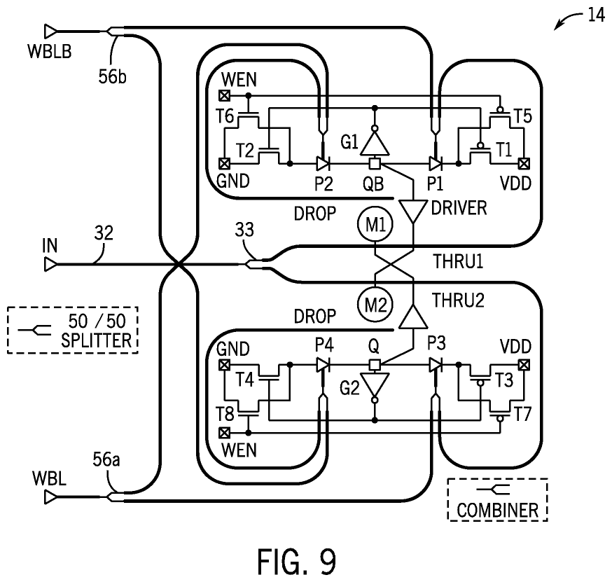

Referring now to FIG. 9, a new state may be written to the memory cell 14 by means of a first write line WBL (being an optical conduit receiving an optical signal to move the bistable state to a SET state). A light signal on WBL moves the memory cell 14 into a first state with Q high (and QB low). Conversely, a second WBLB line (being an optical conduit receiving an optical signal to move the bistable state to a RESET state) may move the memory cell 14 into a second state with QB low (and Q high). The WBL line is received by a splitter 56a so that light is conducted to photosensors P2 and P3 (to be merged by combiners with any light to these diodes from the optical modulators M1 or M2) and the light from the WBLB line is received by a splitter 56b so that light is conducted to photosensors P1 and P4 (to be merged by combiners with any light to these diodes from the optical modulators M1 or M2).

Optionally, to improve the speed of this writing process by allowing photosensors P1 and P2 and P3 and P4 to actively participate in that state change, special shunting transistors may be used. For example, shunting transistor T5 placed across T1, shunting transistor T6 placed across T2, shunting transistor T7 placed across T3, and shunting transistor T8 placed across T4. Each of these transistors may be activated by an electrical WEN line providing an electrical signal associated with a writing operation. Note that this WEN line may be set high and may remain high for a series of multiple write operations and thus does not serve as a limiting factor when multiple writes must occur. Normally, the WEN line will be active (producing a shunting of the transistors that block dark current) prior to the writing operation. Generally these shunting transistors can be used in any of the examples described herein according to this teaching. Note that T5 and T7 are switching logically on the inverse of WEN because, as depicted, they are PMOS transistors and T6 and T8 are switching logically on the WEN signal directly because they are NMOS transistors.

### Example 7

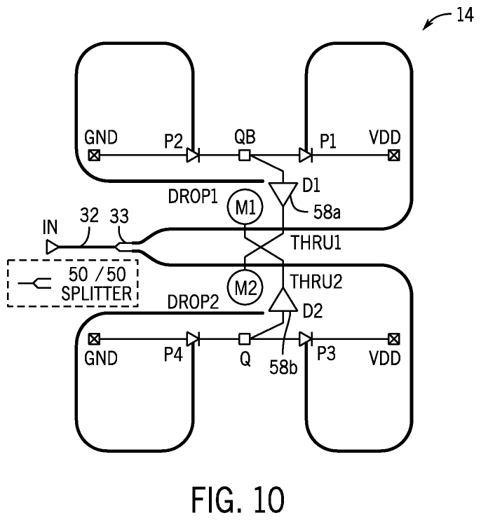

Referring now to FIG. 10, in one embodiment, electrical buffer amplifiers D1 and D2 may be placed between the nodes QB and Q (respectively) and their connected optical modulators M1 or M2. These buffer amplifiers D1 and D2 serve to provide faster charge up of the PN junctions of the optical modulators M1 and M2 which generally have a larger area than typical semiconductor devices and thus a higher electrical capacitance. Again, the buffer amplifier 58 may provide not only a low impedance output but also an internal thresholding and high gain for sharper turn on and turn off of the optical modulators. One possible implementation of the buffer amplifier is two standard CMOS inverters placed in series. Generally these amplifiers D1 and D2 can be favorably combined with any of the examples herein according to this teaching.

### Example 8

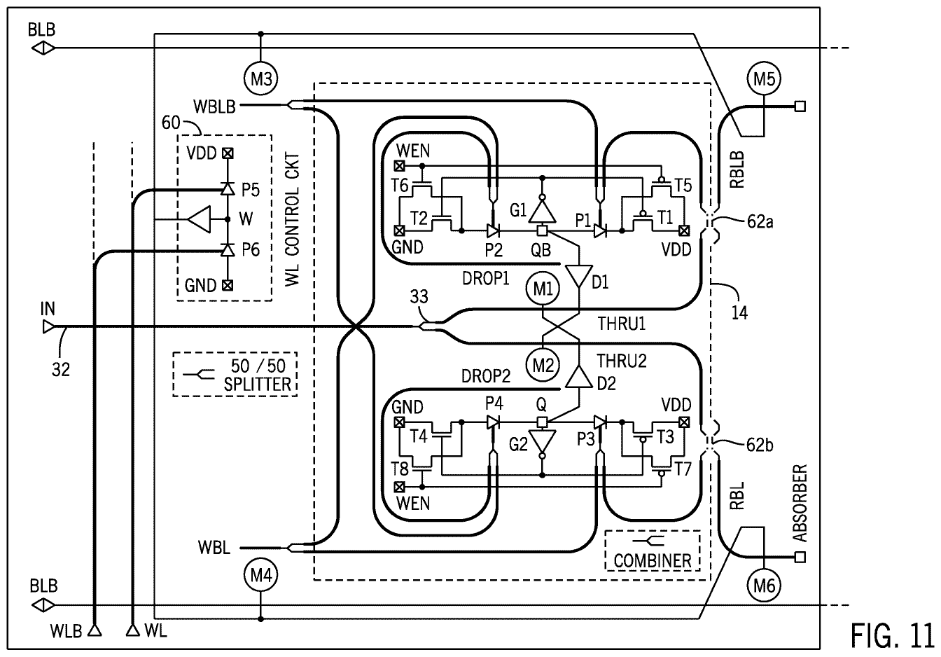

Referring now to FIG. 11, any of the previously described memory cells 14 may intercommunicate with other memory cells 14 in the array 12 of memory cells organized in logical rows and logical columns by means of column write lines WLB and WL being optical conduits that continue upward through the memory cells 14 of each column as indicated by the dotted lines but also branch to connect with photoelectric converter 60. The signals on the column write lines WLB and WL are developed by the laser source 20 (shown in FIG. 1).

These column write lines WLB and WL may be received at a photoelectric converter 60, in this case employing two series connected diodes P5 and P6 back biased between power (VDD) and ground. Specifically photoelectric converter 60a provides a photosensor P5 with its cathode connected to power, and photosensor P6 has its anode connected to ground, and the junction between these photosensors provides node W. Node W communicates electrically with additional electrical switches M3 and M4. When node W is high, it activates switches M3 and M4 to allow a writing to the memory cell 14 from the optical bit lines BLB and BL to conduct light to the inputs of optical modulators M3 and M4. The laser light on these bit lines BLB and BL will have a frequency different from laser 18 and thus M3 and M4 may have a slightly different geometry and tuning than M1 and M2.

When it is desired to write data to the memory cell 14, WLB is set low, and WL is set high causing photosensor P5 to turn on and photosensor P6 to turn off producing a high voltage at junction W. This in turn causes optical modulator M3 to conduct any light on BLB to diodes P1 and P4 and optical modulator M4 to conduct any light on BL to photo sensors P3 and P2 enforcing a desired setting or resetting of the bistable state of the memory cell 14. Generally, if BLB is high (illuminated), BLB and is low, photosensors P1 and P4 will be turned on, and photosensors P2 and P3 will be turned off (representing a state of QB=HIGH), and conversely when BL is high (and BLB is low) the state of Q=HIGH will be achieved.

A reading of the memory cell 14 may be accomplished in the same way, however, with the WLB lines and WB lines used to activate optical modulators M5 and M6 which serve to couple light, respectively, from M1 or M2 to respective bit lines BLB and BL. The light from M1 or M2 represents the state of the memory cell and is now communicated out on the bit lines BLB and BL which may be received by the photodetector array 24 (shown in FIG. 1). This light from M1 or M2 may be tapped from the internal connections between the respective optical modulators M1 and M2 through taps 62a and 62b which may be set up to, for example, split off 10% or less than 30% or less of the light on the connection to transmit on the bit lines BLB or BL without upsetting the amount of light needed to preserve persistence of the state of the memory cell 14.

### Example 9

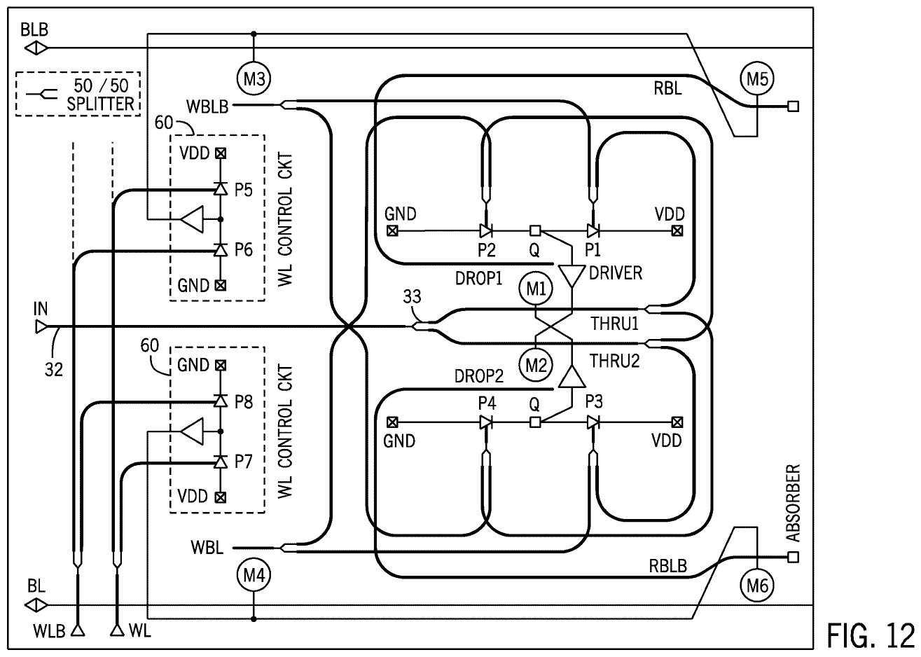

Referring to FIG. 12, readout of the memory cell 14 may be accomplished without the need for a splitter 62 by employing the memory cell structure of FIG. 6 and providing the optical modulators M5 and M6 with connections to the DROP outputs of optical modulators M1 and M2, respectively. An alternative approach to implementing the photoelectric converter 60 is also depicted.

### Example 10

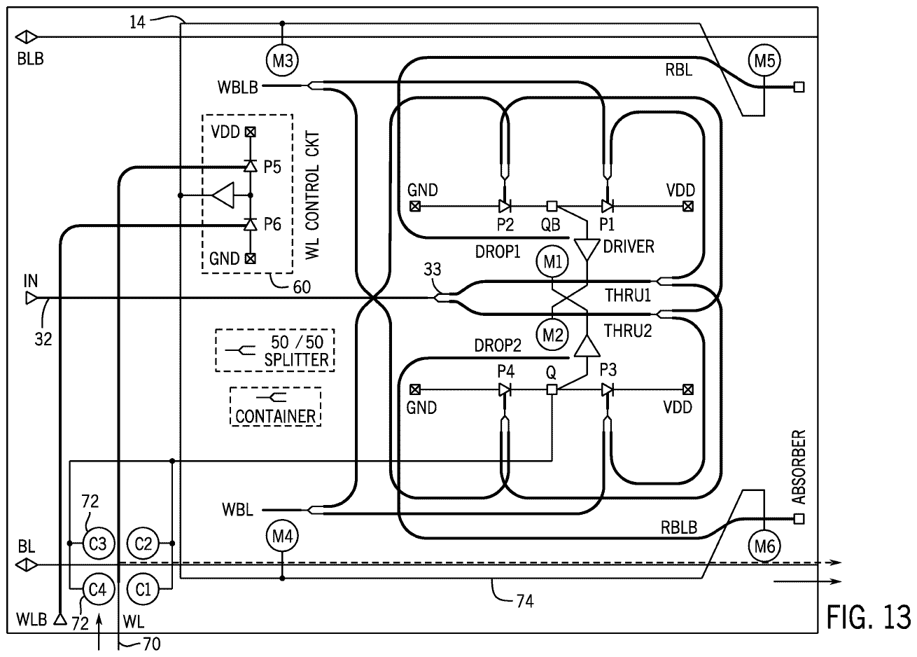

Referring now to FIG. 13, the memory cells 14 discussed above may be used for in-memory computation by providing an operand line 70 (here using the WL line) being an optical conduit carrying one or more desired operand values (single bits) that may be received by one or more computational optical modulators 72 (labeled C1-C4). Generally these optical modulators 72 will have a similar structure to optical modulators M1 and M2 but will be set up for a different frequency of laser light. Generally each of the optical modulators 72 will be optimized to accept and switch light in different distinct frequency bands. The optical modulators 72 may be electrically connected to a node, for example, node Q, to connect or disconnect the light signal from operand line 70 to a product line 74 (here using the pBL line) effecting a multiplication of the operand is 70 with the state of the memory cell 14 reflected by the electrical signal at node Q.

### Example 11

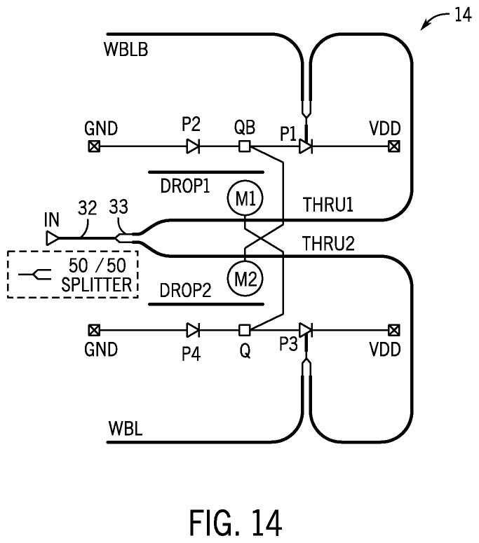

Referring now to FIG. 14, in all of the above embodiments a variation may be implemented in a form where only one photosensors in each series connection (e.g., P1 or P2, or P3 or P4) is switched using light from either an optical modulator (M1 or M2) or from an external write signal. This configuration continues to null out dark current of the photosensors P1-P4 because of the series connection of the photo sensors, although it would be expected that this example will operate at a lower speed because of the reduction in node charging current caused by the elimination of active switching of one of the photo sensors of each pair. The photo sensors which are not switched will desirably still be operable photosensors providing a dark current which tracks the dark current of the active photosensor.

### Example 12

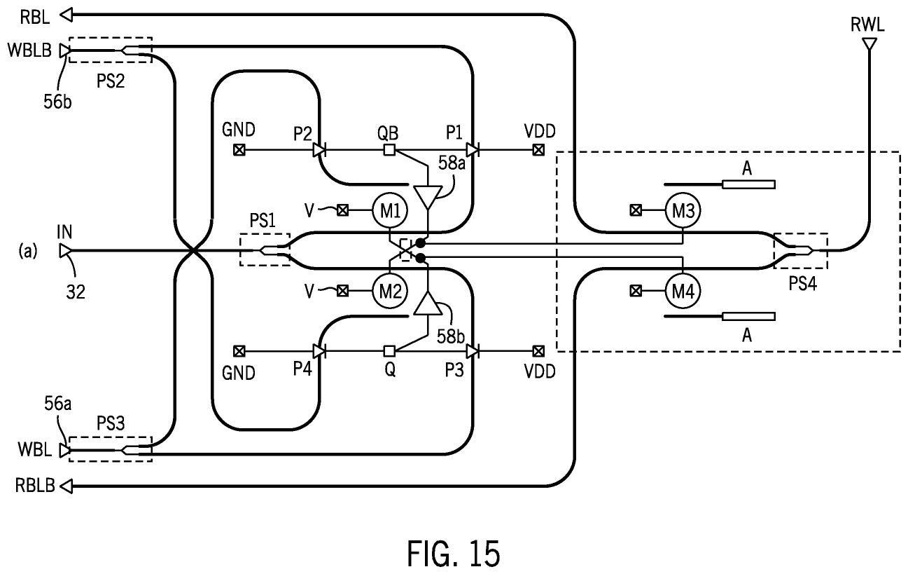

Referring now to FIG. 15, any of the previously described memory cells (in this case the architecture of FIG. 10 is depicted) can be implemented in a form allowing decoupled or independent reading and writing of the memory cell such as can produce read-disturb free operation in which read operations don't interfere with or unintentionally alter the memory cell state.

In this embodiment, a read line (RWL) may receive a light signal passing through a splitter PS4 to interrogate the state of modulators M3 or M4, which are in turn controlled by the same electrical lines controlling M2 and M1 respectively. Depending on the state of M3 and M4, light is shuttled either to output line RBL or RBLB respectively.

Writing occurs by application of optical power to either of write lines WBLB or WBL, where light applied to WBLB passes through optical splitter PS2 to illuminate photo sensors P1 and P4 and light applied to WBL passes through optical splitter PS3 to illuminate photo sensors P2 and P3. The memory cell is otherwise configured in this example as shown in FIG. 10 allowing illumination of these photo sensors to change the state of the memory cell. The optical conduits for the write lines that are used to change the state of the modulators M1 and M2 share the same optical pathway as the light applied through input line 32 that is used to maintain the memory cell state. This sharing is possible because the optical power for writing operates at a higher intensity compared to the light at the input line 32 to temporarily override the light at the input line 32.

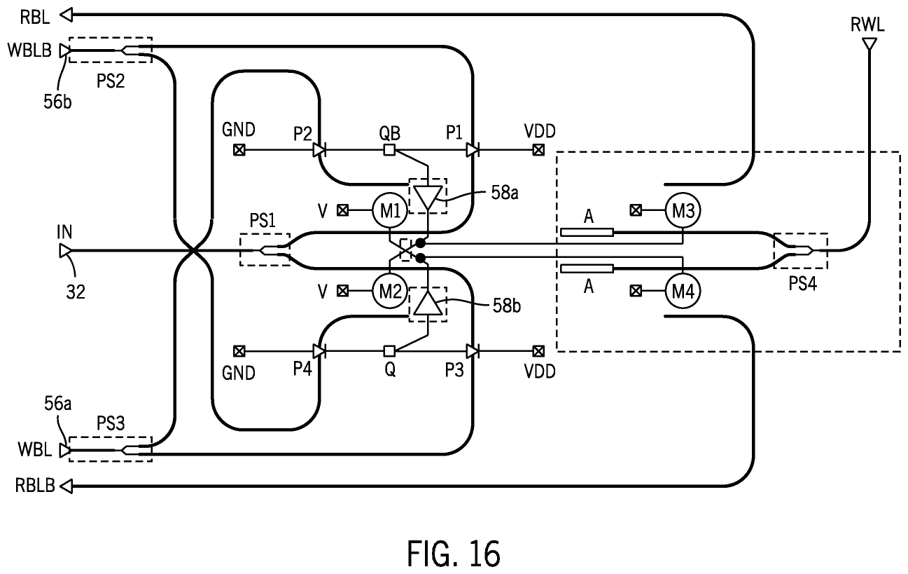

FIG. 16 shows an alternative method of interrogating the modulators M3 and M4 using complementary logic.

Blocks in both FIGS. 15 and 16 labeled A are absorbers and blocks labeled V are thermal ports used for calibration of the modulators M1 and M2.

It will be understood that each of these embodiments provides a different feature that various components of the different embodiments may be combined according to the teachings herein to implement various permutations on the fundamental invention.

Certain terminology is used herein for purposes of reference only, and thus is not intended to be limiting. For example, terms such as “upper”, “lower”, “above”, and “below” refer to directions in the drawings to which reference is made. Terms such as “front”, “back”, “rear”, “bottom” and “side”, describe the orientation of portions of the component within a consistent but arbitrary frame of reference which is made clear by reference to the text and the associated drawings describing the component under discussion. Such terminology may include the words specifically mentioned above, derivatives thereof, and words of similar import. Similarly, the terms “first”, “second” and other such numerical terms referring to structures do not imply a sequence or order unless clearly indicated by the context.

When introducing elements or features of the present disclosure and the exemplary embodiments, the articles “a”, “an”, “the” and “said” are intended to mean that there are one or more of such elements or features. The terms “comprising”, “including” and “having” are intended to be inclusive and mean that there may be additional elements or features other than those specifically noted. It is further to be understood that the method steps, processes, and operations described herein are not to be construed as necessarily requiring their performance in the particular order discussed or illustrated, unless specifically identified as an order of performance. It is also to be understood that additional or alternative steps may be employed.

It is specifically intended that the present invention not be limited to the embodiments and illustrations contained herein and the claims should be understood to include modified forms of those embodiments including portions of the embodiments and combinations of elements of different embodiments as come within the scope of the following claims. All of the publications described herein, including patents and non-patent publications, are hereby incorporated herein by reference in their entireties.

To aid the Patent Office and any readers of any patent issued on this application in interpreting the claims appended hereto, applicants wish to note that they do not intend any of the appended claims or claim elements to invoke 35 U.S.C. 112(f) unless the words “means for” or “step for” are explicitly used in the particular claim.

What we claim is:

1. A memory cell comprising:
a first and second optical modulator having a light input and at least one light output and having an electrical input determining a switching state of the optical modulator defining a switching of light between the light input and light output;
a first photosensor conducting current to a first node according to illumination of the first photosensor and a second photosensor conducting current away from the first node according to the illumination of the second photosensor; and
a third photosensor conducting current to a second node according to the illumination of the third photosensor and a fourth photosensor conducting current away from the second node according to illumination of the fourth photosensor;
wherein the first and second optical modulators control light directed to at least one of a respective photosensor and have their electrical inputs connected to one of the first and second nodes to provide bistable switching states.

2. The memory cell of claim 1 further including a first electrical switch operating to block current flow through the first photosensor when the first node is below a threshold voltage and a second electrical switch operating to block current flow through the second photosensor when the first node is above the threshold voltage; and
a third switch operating to block current flow through the third photosensor when the second node is below the threshold voltage and a fourth electrical switch operating to block current flow through the fourth photosensor when the second node is above the threshold voltage.

3. The memory cell of claim 2 wherein the first and second electrical switches communicate with a first electrical buffer amplifier having an input attached to the first node, and the third and fourth electrical switches communicate with a second electrical buffer amplifier having an input attached to the second node.

4. The memory cell of claim 2 further including:
a fifth electrical switch operating to shunt the first electrical switch and a sixth electrical switch operating to shunt the second electrical switch;
a seventh electrical switch operating to shunt the third electrical switch and an eighth electrical switch operating to shunt the fourth electrical switch; and
wherein the fifth, sixth, seventh, and eighth electrical switches are adapted to receive a write signal to move them to a shunting state during a writing of data to the memory cell, such writing as operates to change the bistable switching state.

5. The memory cell of claim 1 wherein the first and second optical modulators each have a light input receiving light that can be switchably directed to either of a THROUGH output or a DROP output and wherein the first and second optical modulators control illumination of the first, second, third, and fourth photosensors by conducting light to the respective photosensors from the DROP light output.

6. The memory cell of claim 1 wherein the first optical modulator controls light to the first and second photosensors and the second optical modulator controls light to the third and fourth photosensors and wherein the second optical modulator is connected to the first node and the first optical modulator is connected to the second node.

7. The memory cell of claim 1 wherein the first optical modulator controls light to the third and fourth photosensors and the second optical modulator controls light to the first and second photosensors and wherein the second optical modulator is connected to the second node and the first optical modulator is connected to the first node.

8. The memory cell of claim 1 further including two optical conduits receiving a SET signal or RESET signal, respectively, to change the bistable switching state and operating to conduct light each to a photosensor associated with a different node.

9. The memory cell of claim 1 further including two optical conduits each connected to communicate with a different one of the optical modulators to provide a light output indicating the bistable switching state.

10. The memory cell of claim 9 wherein the optical conduits communicate with respective optical modulators using a splitter transmitting less than 30% of the light from the optical modulator to the optical conduit.

11. The memory cell of claim 9 wherein the optical conduits are connected directly to an output of an optical modulator not providing light to a photosensor.

12. The memory cell of claim 1 further including an optical conduit for receiving an operand signal and further including at least one third optical modulator communicating with at least one of the nodes to switch light to a second product output optical conduit depending on the state of the bistable element.

13. The memory cell of claim 1 further including multiple third optical modulators each communicating with one of the nodes to switch light to a second product output optical conduit depending on the state of the bistable element;
wherein the multiple third optical modulators each provide a different on-state frequency offset of a passband or rejection band.

14. The memory cell of claim 1 wherein the first optical modulator switches light alternately between the first photosensor and second photosensor and the second optical modulator switches light alternately between the third photosensor and the fourth photosensor.

15. The memory cell of claim 1 wherein the optical modulators are selected from the group consisting of a micro ring resonator optical modulator and a Mach Zehnder interferometric optical modulator.

16. The memory cell of claim 1 wherein the photosensors are selected from the group consisting of a phototransistor and a photo diode.

17. A memory system comprising:
an array of memory cells arranged in logical rows and columns and each providing:
a first and second optical modulator having a light input and at least one light output and having an electrical input determining a switching state of the optical modulator defining a switching of light between the light input and light output;
a first photosensor conducting current to a first node determined by illumination of the first photosensor and a second photosensor conducting current away from the first node determined by illumination of the second photosensor;
a third photosensor conducting current to a second node determined by illumination of the third photosensor and a fourth photosensor conducting current away from the second node determined by illumination of the fourth photosensor;
wherein the first and second optical modulators control light directed to the photosensors and have their electrical inputs connected to one of the first and second nodes to provide bistable switching states;
a set of electrical write lines communicating with the memory cells along a logical column; and
a set of optical bit lines communicating with the memory cells along a logical row;
wherein the memory cells include at least one third optical modulator communicating with an electrical write line and connecting at least one optical bit line to at least one photosensor to change a bistable state of the memory cell according to the signal on the electrical write line.

18. The memory system of claim 17 further including at least one fourth optical modulator communicating with the electrical write line and connecting at least one optical bit line to an output of at least one optical modulator to read a state of the bistable state of the memory cell according to the signal on the electrical write line.
